(19) United States
(12) Patent Application Publication
(10) Pub. No.: US 2026/0123255 A1
(43) Pub. Date: Apr. 30, 2026

(54) DISPLAY DEVICE AND ELECTRONIC DEVICE INCLUDING THE SAME

(71) Applicant: Samsung Display Co., Ltd., Yongin-si (KR)

(72) Inventor: Gi-Na YOO, Yongin-si (KR)

(73) Assignee: Samsung Display Co., Ltd., Yongin-si (KR)

(21) Appl. No.: 19/295,795

(22) Filed: Aug. 11, 2025

(30) Foreign Application Priority Data
Oct. 30, 2024 (KR) 10-2024-0150884

(51) Int. Cl. H10K 59/80; H10K 59/122; H10K 59/38; H10K 102/00

(52) U.S. Cl. CPC H10K 59/8792; H10K 59/122; H10K 59/38; H10K 2102/311; H10K 2102/351

(57) ABSTRACT

A display device includes a display panel including a plurality of light-emitting elements, a folding part including a (1-1)-th light-emitting element, a (2-1)-th light-emitting element, and a (3-1)-th light-emitting element, and a non-folding part adjacent to the folding part, the non-folding part including a first light-emitting element, a second light-emitting element, and a third light-emitting element, a plurality of color filters on the display panel and overlapping the plurality of light-emitting elements when viewed on a plane, and a black matrix between the plurality of color filters, wherein, when viewed on the plane, a first portion of the black matrix between the first light-emitting element and the third light-emitting element has a first width, and wherein a second portion of the black matrix between the (1-1)-th light-emitting element and the (3-1)-th light-emitting element has a second width different from the first width.

### CROSS-REFERENCE TO RELATED APPLICATIONS

This U.S. non-provisional patent application claims priority under 35 U.S.C. § 119 to Korean Patent Application No. 10-2024-0150884, filed on Oct. 30, 2024, the entire contents of which are hereby incorporated by reference.

### BACKGROUND

Generally, a display device includes a display module for displaying images, and a support part for supporting the display module. The display module includes a display panel which displays images, a window which is disposed on the display panel and protects the display panel against external scratches and impacts, and a protective layer which is disposed below the display panel and protects the display panel against external impacts.

Recently, with the technological development for the display devices, a flexible display device, which is deformable into various shapes, is being developed. A flexible display device includes a flexible display module which is foldable and rollable.

### SUMMARY

Example embodiments of the inventive concepts provide a display device including a display panel a folding part of which has improved visibility when the flexible display device is folded, and an electronic device including the same.

Some example embodiments of the inventive concepts provide a display device including a display panel including a plurality of light emitting elements, a folding part including a (1-1)-th light-emitting element, a (2-1)-th light-emitting element, and a (3-1)-th light-emitting element, and a non-folding part adjacent to the folding part, the non-folding part including a first light-emitting element, a second light-emitting element, and a third light-emitting element, a plurality of color filters on the display panel, the plurality of color filters overlapping the plurality of light-emitting elements when viewed on a plane, and a black matrix between the plurality of color filters, wherein when viewed on the plane, a first portion of the black matrix between the first light-emitting element and the third light-emitting element has a first width, and wherein a second portion of the black matrix between the (1-1)-th light-emitting element and the (3-1)-th light-emitting element has a second width different from the first width.

In some example embodiments, the folding part and the non-folding part may be adjacent to each other in a first direction, the first light-emitting element and the third light-emitting element may be adjacent to each other in the first direction, and the (1-1)-th light-emitting element and the (3-1)-th light-emitting element may be adjacent to each other in the first direction, and the first width and the second width may be widths with respect to the first direction.

In some example embodiments, the display device may further include a (1-2)-th light-emitting element and a (3-2)-th light-emitting element adjacent to each other in the first direction and in a row with the (1-1)-th light emitting element and the (3-1)-th light-emitting element in the first direction, wherein when viewed on the plane, a third portion of the black matrix between the (1-2)-th light-emitting element and the (3-2)-th light-emitting element in the first direction may have a third width different from the first width and the second width in the first direction.

In some example embodiments, the (1-2)-th light-emitting element and the (3-2)-th light-emitting element may be in the folding part.

In some example embodiments, the first width may be greater than the second width.

In some example embodiments, the third width may be greater than the first width.

In some example embodiments, the first, second, and third portions of the black matrix may have a same thickness.

In some example embodiments, a first thickness of the first portion, a second thickness of the second portion, and a third thickness of the third portion may be different from each other in a direction perpendicular to the plane.

In some example embodiments, the first thickness may be greater than the second thickness.

In some example embodiments, the third thickness may be greater than the first thickness.

In some example embodiments, the display device may further include a pixel-defining film defining a plurality of pixel openings exposing the plurality of light-emitting elements, wherein the black matrix may define a plurality of openings overlapping the pixel openings, and wherein an area of a respective opening may be greater than an area of the pixel opening the respective opening overlaps.

In some example embodiments, the first width, the second width, and the third width may be adjacent to each other in the first direction, and may be distances between the openings which respectively define the first, second, and third widths.

In some example embodiments, the first light-emitting element, the (1-1)-th light-emitting element, and the (1-2)-th light-emitting element may be configured to generate a red color, the second light-emitting element and the (2-1)-th light-emitting element may be configured to generate a green color, and the third light-emitting element, the (3-1)-th light-emitting element, and the (3-2)-th light-emitting element may be configured to generate a blue color.

In some example embodiments, the second portion having the second width and the third portion having the third width may be alternately arranged in the first direction.

In some example embodiments of the inventive concepts, a display device includes a plurality of light-emitting elements, a display panel including a folding part including a (1-1)-th light-emitting element, a (1-2)-th light-emitting element, a (2-1)-th light-emitting element, a (3-1)-th light-emitting element, and a (3-2)-th light-emitting element, and a non-folding part adjacent to the folding part, the non-folding part including a first light-emitting element, a second light-emitting element, and a third light-emitting element, a plurality of color filters on the display panel and overlapping the plurality of light-emitting elements when viewed on a plane; and a black matrix between the plurality of color filters, wherein when viewed on the plane, a first portion of the black matrix between the first light-emitting element and the third light-emitting element has a first width, a second portion of the black matrix between the (1-1)-th light-emitting element and the (3-1)-th light-emitting element has a second width, and a third portion of the black matrix between the (1-2)-th light-emitting element and the (3-2)-th light-emitting element has a third width, and wherein the third width is greater than the first width, and the first width is greater than the second width.

In some example embodiments, the second portion having the second width and the third portion having the third width may be alternately arranged in the first direction.

In some example embodiments, a first thickness of the first portion, a second thickness of the second portion, and a third thickness of the third portion may be different from each other in a direction perpendicular to the plane.

In some example embodiments, the first width, the second width, and the third width of the black matrix may be equal to each other, the third thickness may be greater than the first thickness, and the first thickness may be greater than the second thickness.

In some example embodiments of the inventive concepts, an electronic device includes: a camera, a display device configured to display an image corresponding to a captured image obtained via the camera; and a case accommodating the display device and the camera, wherein the display device includes a plurality of light-emitting elements, a display panel including a folding part including a (1-1)-th light-emitting element, a (2-1)-th light-emitting element, and a (3-1)-th light-emitting element, and a non-folding part adjacent to the folding part, the non-folding part including a first light-emitting element, a second light-emitting element, and a third light-emitting element, a plurality of color filters on the display panel and overlapping the plurality of light-emitting elements when viewed on a plane, and a black matrix between the plurality of color filters, and wherein, when viewed on the plane, a first portion of the black matrix between the first light-emitting element and the third light-emitting element has a first width, and a second portion of the black matrix between the (1-1)-th light-emitting element and the (3-1)-th light-emitting element has a second width different from the first width.

### BRIEF DESCRIPTION OF THE FIGURES

The accompanying drawings are included to provide a further understanding of the inventive concepts, and are incorporated in and constitute a part of this specification. The drawings illustrate some example embodiments of the inventive concepts and, together with the description, serve to explain principles of the inventive concepts. In the drawings:

FIG. 1 is a perspective view of an electronic device according to some example embodiments of the inventive concepts;

FIG. 2 is a view illustrating a state in which the electronic device illustrated in FIG. 1 is folded;

FIG. 3 is an exploded perspective view of the electronic device illustrated in FIG. 1;

FIG. 4 is a block diagram of the electronic device illustrated in FIG. 3;

FIG. 5 is an example of a cross-sectional view of the display device illustrated in FIG. 3;

FIG. 6 is an example of a cross-sectional view of the display panel illustrated in FIG. 3;

FIG. 7 is a plan view of a display panel illustrated in FIG. 5;

FIG. 8 is an example of a cross-sectional view of one pixel illustrated in FIG. 7;

FIG. 9 is a plan view of the display device illustrated in FIG. 5;

FIG. 10 is an example of a cross-sectional view of some pixels adjacent to each other and an anti-reflection layer corresponding to the pixels in a non-folding part;

FIG. 11 is an example of a cross-sectional view of some pixels adjacent to each other and an anti-reflection layer corresponding to the pixels in a non-folding part;

FIG. 12 is an example of a cross-sectional view of some pixels adjacent to each other and an anti-reflection layer corresponding to the pixels in a folding part;

FIG. 13A is an enlarged view of a folding part and a non-folding part;

FIG. 13B is a graph showing luminances of the folding part and the non-folding part;

FIG. 14 is an example of a cross-sectional view of some pixels adjacent to each other and an anti-reflection layer corresponding to the pixels in a non-folding part;

FIG. 15 is an example of a cross-sectional view of some pixels adjacent to each other and an anti-reflection layer corresponding to the pixels in a folding part; and

FIG. 16 is an example of a cross-sectional view of some pixels adjacent to each other and an anti-reflection layer corresponding to the pixels in a folding part.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc., may be used herein to describe various elements, the elements are not to be limited by these terms. These terms are only used to distinguish one element, component, region, layer or section from another element, component, region, layer or section. For instance, a first element could be termed a second element without departing from the scope of the inventive concepts. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

When an element is referred to as being “connected to” or “electrically connected to” another element, the element may be directly connected to the other element, or one or more other intervening elements may be present. For example, an element described as being “connected to” another element may be “electrically connected to” the other element. In contrast, when an element is referred to as being “directly connected to” another element there are no intervening elements present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

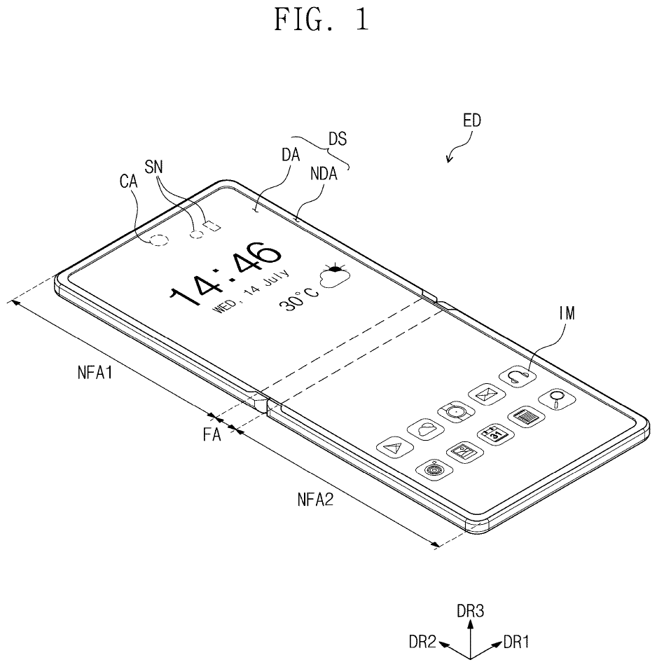

FIG. 1 is a perspective view of an electronic device according to some example embodiments of the inventive concepts.

Referring to FIG. 1, an electronic device ED according to some example embodiments of the inventive concepts may have a rectangular shape which has short sides extending in a first direction DR1 and long sides extending in a second direction DR2 crossing the first direction DR1. However, example embodiments of the inventive concepts are not limited thereto, and the electronic device ED may have various shapes, such as a circular or polygonal shape. The electronic device ED may be a flexible electronic device.

Hereinafter, a direction, which is substantially perpendicular to a plane defined by the first direction DR1 and the second direction DR2, is defined as a third direction DR3. Also, in this specification, the wording, “when viewed on a plane” may be defined as a state when viewed in the third direction DR3. Additionally, in this specification, the wording, “overlapping” may be referred to as a state in which components are disposed to overlap each other when viewed on a plane.

The electronic device ED may include a folding part FA and/or a plurality of non-folding parts NFA1 and/or NFA2. The non-folding parts NFA1 and/or NFA2 may include a first non-folding part NFA1 and/or a second non-folding part NFA2. The folding part FA may be disposed between the first non-folding part NFA1 and the second non-folding part NFA2. The first non-folding part NFA1, the folding part FA, and the second non-folding part NFA2 may be arranged in the second direction DR2.

One folding part FA and two non-folding parts NFA1 and NFA2 are illustrated as an example, but the number of the folding part FA and the number of the non-folding parts NFA1 and NFA2 are not limited thereto. For example, the electronic device ED may include more than two non-folding parts and/or a plurality of folding parts disposed with the non-folding parts therebetween.

An upper surface of the electronic device ED may be defined as a display surface DS and have a flat surface defined by the first direction DR1 and the second direction DR2. Images IM generated from the electronic device ED may be provided to users through the display surface DS.

The display surface DS may include a display region DA and/or a non-display region NDA around the display region DA. The display region DA may display images, and the non-display region NDA may not display images. The non-display region NDA may surround the display region DA and define a border of the electronic device ED printed in a predetermined color.

The electronic device ED may include a plurality of sensors SN and/or at least one camera CA. The sensors SN and/or the camera CA may be adjacent to the border of the electronic device ED. The sensors SN and/or the camera CA may be disposed in the display region DA adjacent to the non-display region NDA. The sensors SN and/or the camera CA may be disposed in the first non-folding part NFA1, but the positions at which the sensors SN and/or the camera CA are disposed are not limited thereto.

For example, the sensors SN may be proximity luminance sensors, but the types of the sensors SN are not limited thereto. The camera CA may capture an external image.

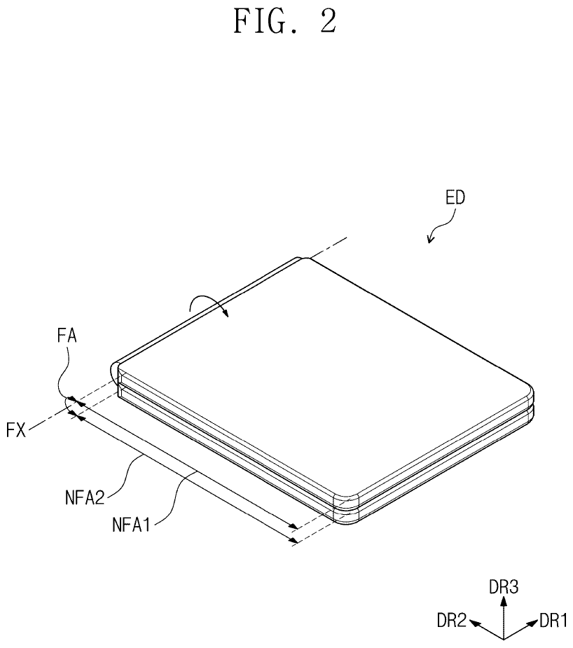

FIG. 2 is a view illustrating a state in which the electronic device illustrated in FIG. 1 is folded.

Referring to FIG. 2, an electronic device ED may be a foldable electronic device ED which is folded or unfolded. For example, the electronic device ED may be folded such that the folding part FA is bent with respect to a folding axis FX parallel to the first direction DR1. The folding axis FX may be defined as a short axis parallel to a short side of the electronic device ED.

When the electronic device ED is folded, the electronic device ED may be in-folded such that the first non-folding part NFA1 and the second non-folding part NFA2 face each other and the display surface DS is not exposed to the outside. However, example embodiments of the inventive concepts are not limited thereto. For example, the electronic device ED may also be out-folded with respect to the folding axis FX such that the display surface DS is exposed to the outside.

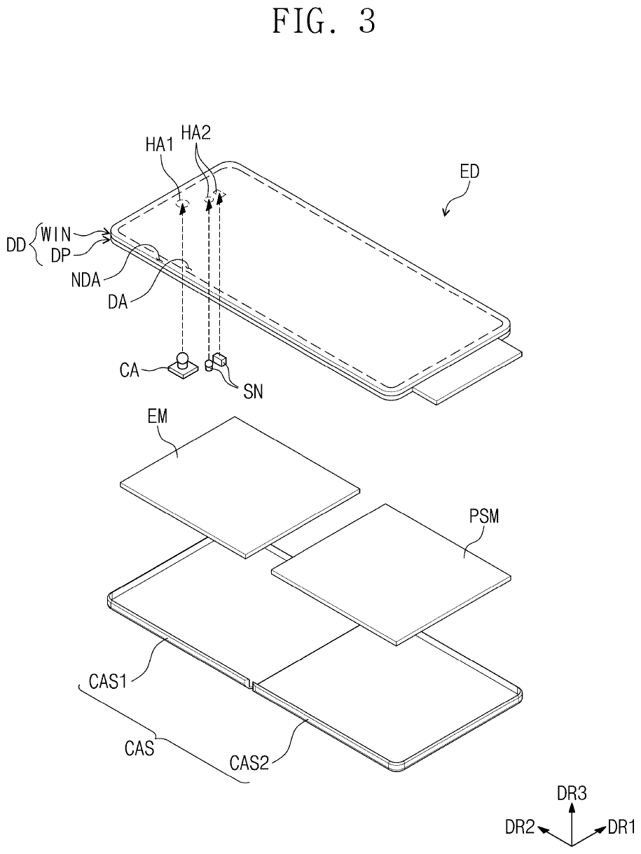

FIG. 3 is an exploded perspective view of the electronic device illustrated in FIG. 1.

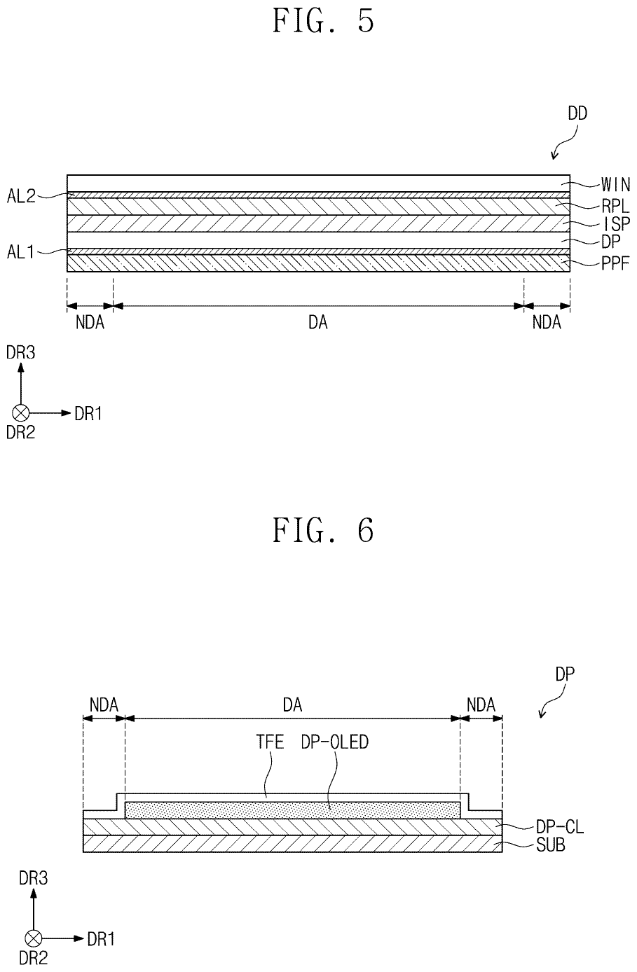

Referring to FIG. 3, an electronic device ED may include a display device DD, a camera CA, sensors SN, an electronic module EM, a power supply module PSM, and/or cases CAS1 and/or CAS2. The display device DD may include a display panel DP and/or a window WIN disposed on the display panel DP. The window WIN may be disposed on the display panel DP and protect the display panel DP against external scratches. For example, the display panel DP and the window WIN of the display device DD are illustrated, but the display device DD may further include an input-sensing unit and/or an anti-reflection layer disposed between the display panel DP and the window WIN. This configuration will be described below with reference to FIG. 5. Although not illustrated separately, the electronic device ED may further include mechanical structures for controlling a folding operation of the display device DD.

The camera CA and/or the sensors SN may be disposed below the display device DD. First and second hole regions HA1 and HA2 may be defined in the display device DD, the camera CA may be disposed in the first hole regions HA1, and the sensors SN may be disposed in the second hole regions HA2.

The electronic module EM and/or the power supply module PSM may be disposed below the display device DD. Although not illustrated, the electronic module EM and the power supply module PSM may be connected to each other via a flexible circuit board. The electronic module EM may control an operation of the display device DD. The power supply module PSM may supply power to the electronic module EM.

The cases CAS1 and/or CAS2 may accommodate the display device DD, the electronic module EM, and/or the power supply module PSM. The cases CAS1 and/or CAS2 may be divided into two first and second cases CAS1 and CAS2 so as to allow the display device DD to be folded. The cases CAS1 and/or CAS2 may protect the display device DD, the electronic module EM, and/or the power supply module PSM.

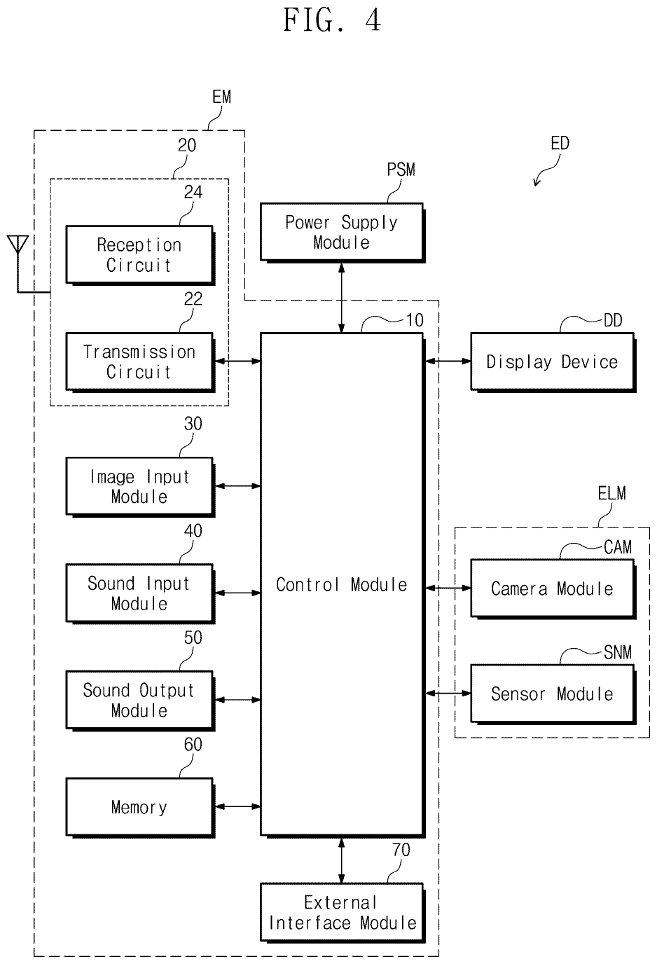

FIG. 4 is a block diagram of the electronic device illustrated in FIG. 3.

Referring to FIG. 4, an electronic device ED may include an electronic module EM, a power supply module PSM, a display device DD, and/or an electro-optical module ELM. The electronic module EM may include a control module 10, a wireless communication module 20, an image input module 30, a sound input module 40, a sound output module 50, a memory 60, and/or an external interface module 70, etc. The modules may be mounted on a circuit board or be electrically connected via a flexible circuit board. The electronic module EM may be electrically connected to the power supply module PSM.

The control module 10 may control an overall operation of the electronic device ED. For example, the control module 10 may activate or deactivate the display device DD in accordance with a user's input. The control module 10 may control the image input module 30, the sound input module 40, and/or the sound output module 50, etc., in accordance with a user's input. The control module 10 may include at least one microprocessor.

The wireless communication module 20 may transmit/receive wireless signals to/from another terminal via a Bluetooth and/or Wi-Fi line. The wireless communication module 20 may transmit/receive voice signals via a general communication line. The wireless communication module 20 may include a transmission circuit 22 which modulates and transmits a signal to be transmitted, and/or a reception circuit 24 which demodulates a received signal.

The image input module 30 may process image signals and convert the signals into displayable image data on the display device DD. The sound input module 40 may receive an input of an external sound signal via a microphone in a recording mode and/or voice recognition mode, etc., and convert the signal into electrical voice data. The sound output module 50 may convert sound data received from the wireless communication module 20 and/or sound data stored in the memory 60 and output the converted sound data to the outside.

The external interface module 70 may serve as an interface which is connected to an external charger, a wired/wireless data port, and/or a card socket (for example, a memory card, a SIM/UIM card), etc.

The power supply module PSM may supply power for overall operations of the electronic device ED. The power supply module PSM may include a typical battery device.

The electro-optical module ELM may be an electronic component which outputs and/or receives optical signals. The electro-optical module ELM may transmit and/or receive optical signals through some regions of the display device DD. Some example embodiments, the electro-optical module ELM may include a camera module CAM and/or a sensor module SNM. The camera module CAM may include the camera CA illustrated in FIG. 3. The sensor module SNM may include the sensor SN illustrated in FIG. 3.

The electronic device ED may include the camera module CAM, and/or the display device DD which displays images corresponding to captured images obtained via the camera module CAM.

FIG. 5 is an example of a cross-sectional view of the display device illustrated in FIG. 3.

For example, FIG. 5 illustrates a cross section of the display device DD when viewed in the second direction DR2.

Referring to FIG. 5, a display device DD may include a display panel DP, an input-sensing unit ISP, an anti-reflection layer RPL, a window WIN, a panel protection film PPF, and/or first and/or second adhesive layers AL1 and AL2.

The display panel DP according to some example embodiments of the inventive concepts may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, etc. Hereinafter, the display panel DP is described as an organic light-emitting display panel.

The input-sensing unit ISP may be disposed on the display panel DP. The input-sensing unit ISP may include a plurality of sensing units (not illustrated) for sensing an external input in a capacitive manner. The input-sensing unit ISP may be directly manufactured on the display panel DP when the display device DD is manufactured. However, some example embodiments of the inventive concepts are not limited thereto. The input-sensing unit ISP may be manufactured as a panel separately from the display panel DP, and then attached to the display panel DP via an adhesive layer.

The anti-reflection layer RPL may be disposed on the input-sensing unit ISP. The anti-reflection layer RPL may be directly manufactured on the input-sensing unit ISP when the display device DD is manufactured. However, some example embodiments of the inventive concepts are not limited thereto. The anti-reflection layer RPL may be separately manufactured as a panel, and then attached to the input-sensing unit ISP via an adhesive layer.

The anti-reflection layer RPL may be defined as an external light anti-reflection film. The anti-reflection layer RPL may reduce reflectance for external light which enters the display panel DP from above the display device DD. Due to the anti-reflection layer RPL, the external light may not be viewed by a user.

When external light propagating toward the display panel DP is reflected at the display panel DP and is re-provided to an external user, the external light may be viewed by the user as if reflected from a mirror. In order to reduce or prevent this phenomenon, the anti-reflection layer RPL may include, for example, a plurality of color filters which display the same colors as pixels of the display panel DP.

The color filters may filter external light with colors the same as those of pixels. In this case, the external light may be invisible to a user. However, some example embodiments of the inventive concepts are not limited thereto, and the anti-reflection layer RPL may include a retarder and/or a polarizer for reducing the reflectance for external light.

The window WIN may be disposed on the anti-reflection layer RPL. The window WIN may protect the display panel DP, the input-sensing unit ISP, and/or the anti-reflection layer RPL against external scratches and impacts.

The panel protection film PPF may be disposed below the display panel DP. The panel protection film PPF may protect a lower part of the display panel DP. The panel protection film PPF may include a flexible plastic material such as polyethyleneterephthalate (PET).

The first adhesive layer AL1 may be disposed between the display panel DP and the panel protection film PPF, and the display panel DP and the panel protection film PPF may be bonded to each other via the first adhesive layer AL1. The second adhesive layer AL2 may be disposed between the window WIN and the anti-reflection layer RPL, and the window WIN and the anti-reflection layer RPL may be bonded to each other via the second adhesive layer AL2.

FIG. 6 is an example of a cross-sectional view of the display panel illustrated in FIG. 3.

For example, FIG. 3 illustrates a cross section of the display panel DP when viewed in the second direction DR2.

Referring to FIG. 6, a display panel DP may include a substrate SUB, a circuit element layer DP-CL disposed on the substrate SUB, a display element layer DP-OLED disposed on the circuit element layer DP-CL, and/or a thin-film encapsulation layer TFE disposed on the display element layer DP-OLED.

The substrate SUB may include a display region DA and/or a non-display region NDA around the display region DA. The substrate SUB may include glass and/or a flexible plastic material such as polyimide (PI). The display element layer DP-OLED may be disposed in the display region DA.

A plurality of pixels may be disposed on the circuit element layer DP-CL and/or the display element layer DP-OLED. The pixels may each, or one or more, include a transistor disposed on the circuit element layer DP-CL, and/or a light-emitting element disposed on the display element layer DP-OLED and connected to the transistor.

The thin-film encapsulation layer TFE may be disposed on the circuit element layer DP-CL so as to cover the display element layer DP-OLED. The thin-film encapsulation layer TFE may protect the pixels against moisture, oxygen, and/or external foreign substances.

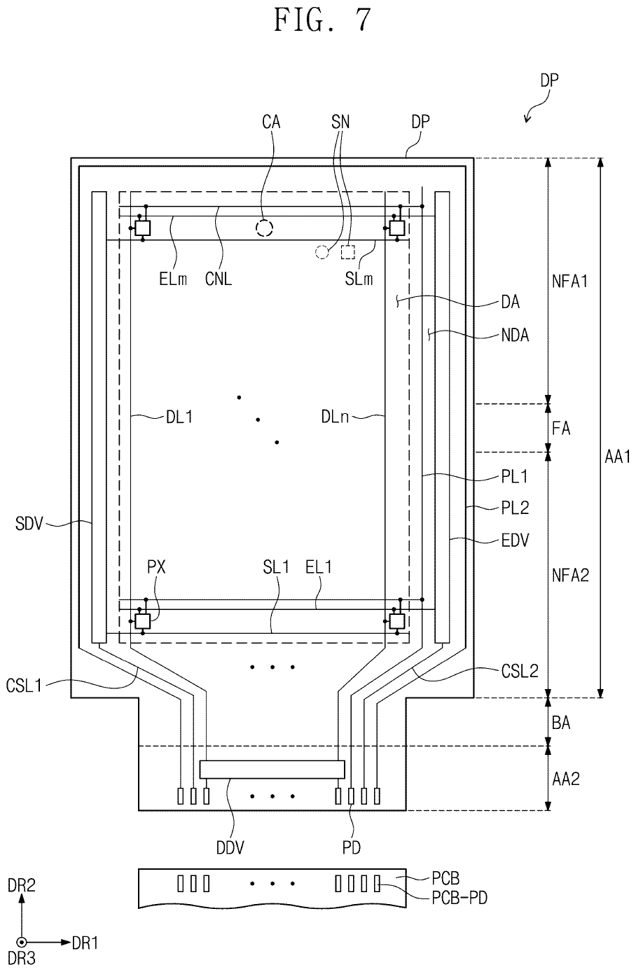

FIG. 7 is a plan view of the display panel illustrated in FIG. 5.

Referring to FIG. 7, a display panel DP may include a scan driver SDV, a data driver DDV, and/or an emission driver EDV.

The display panel DP according to some example embodiments of the inventive concepts may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, etc. Hereinafter, the display panel DP is described as an organic light-emitting display panel.

The display panel DP may be a flexible display panel. For example, the display panel DP may include a plurality of electronic elements disposed on a flexible substrate. The display panel DP may extend longer in the second direction DR2 than in the first direction DR1. The display panel DP may have a plane defined by the first and second directions DR1 and DR2.

The display panel DP may include a first region AA1, a second region AA2, and/or a bending region BA disposed between the first region AA1 and the second region AA2. The bending region BA may extend in the first direction DR1, and the first region AA1, the bending region BA, and the second region AA2 may be arranged in the second direction DR2.

The first region AA1 may have long sides which are opposite to each other in the first direction DR1, and extend in the second direction DR2. The lengths of the bending region BA and the second region AA2 may be smaller than the length of the first region AA1 with respect to the first direction DR1.

The first region AA1 may include a display region DA and/or a non-display region NDA around the display region DA. The non-display region NDA may surround the display region DA. The display region DA may display images, and the non-display region NDA may not display images. The second region AA2 and/or the bending region BA may not display images. The sensors SN and/or the camera CA may be disposed in the display region DA.

The first region AA1 may include a first non-folding part NFA1, a second non-folding part NFA2, and/or a folding part FA disposed between the first non-folding part NFA1 and the second non-folding part NFA2. The first non-folding part NFA1, the folding part FA, and the second non-folding part NFA2 of the display panel DP may respectively correspond to the first non-folding part NFA1, the folding part FA, and the second non-folding part NFA2 of the display device DD illustrated in FIG. 1.

The display panel DP may include a plurality of pixels PX, a plurality of scan lines SL1 to SLm, a plurality of data lines DL1 to DLn, a plurality of emission lines EL1 to ELm, first and/or second control lines CSL1 and/or CSL2, a first power supply line PL1, a second power supply line PL2, a plurality of connection lines CNL, and/or a plurality of pads PD. m and n are natural numbers. The pixels PX may be disposed in the display region DA and be connected to the scan lines SL1 to SLm, the data lines DL1 to DLn, and/or the emission lines EL1 to ELm.

The scan driver SDV and/or the emission driver EDV may be disposed in the non-display region NDA. The scan driver SDV and/or the emission driver EDV may be disposed in the non-display region NDA adjacent to the respective long sides of the first region AA1. The data driver DDV may be disposed on the second region AA2. The data driver DDV may be manufactured in a form of an integrated circuit chip and be mounted on the second region AA2.

The scan lines SL1 to SLm may extend in the first direction DR1 to be connected to the scan driver SDV. The data lines DL1 to DLn may extend in the second direction DR2 to be connected to the data driver DDV via the bending region BA. The emission lines EL1 to ELm may extend in the first direction DR1 to be connected to the emission driver EDV.

The first power supply line PL1 may extend in the second direction DR2, and be disposed in the non-display region NDA. The first power supply line PL1 may be disposed between the display region DA and the emission driver EDV. However, some example embodiments of the inventive concepts are not limited thereto, and the first power supply line PL1 may also be disposed between the display region DA and the scan driver SDV.

The first power supply line PL1 may extend to the second region AA2 via the bending region BA. The first power supply line PL1 may extend toward a lower end of the second region AA2 when viewed on a plane. The first power supply line PL1 may receive a first voltage.

The second power supply line PL2 may be disposed both in the non-display region NDA adjacent to long sides of the first region AA1 and in the non-display region NDA facing the second region AA2 with the display region DA therebetween. The second power supply line PL2 may be disposed further outside than the scan driver SDV and/or the emission driver EDV.

The second power supply line PL2 may extend to the second region AA2 via the bending region BA. In the second region AA2, the second power supply line PL2 may extend in the second direction DR2 with the data driver DDV therebetween. The second power supply line PL2 may extend toward the lower end of the second region AA2 when viewed on a plane.

The second power supply line PL2 may receive a second voltage having a lower level than that of the first voltage. Although the connection relationship is not illustrated for convenience, the second power supply line PL2 may extend to the display region DA to be connected to the pixels PX, and the second voltage may be supplied to pixels PX via the second power supply line PL2.

The connection lines CNL may extend in the first direction DR1 and be arranged in the second direction DR2. The connection lines CNL may be connected to the first power supply line PL1 and/or the pixels PX. The first voltage may be applied to the pixels PX via the first power supply line PL1 and the connection lines CNL which are connected to each other.

The first control line CSL1 may be connected to the scan driver SDV and extend toward the lower end of the second region AA2 via the bending region BA. The second control line CSL2 may be connected to the emission driver EDV and extend toward the lower end of the second region AA2 via the bending region BA. The data driver DDV may be disposed between the first control line CSL1 and the second control line CSL2.

When viewed on a plane, the pads PD may be disposed adjacent to the lower end of the second region AA2. The data driver DDV, the first power supply line PL1, the second power supply line PL2, the first control line CSL1, and/or the second control line CSL2 may be connected to the pads PD.

The data lines DL1 to DLn may be connected to corresponding pads PD via the data driver DDV. For example, the data lines DL1 to DLn may be connected to the data driver DDV, and the data driver DDV may be connected to the pads PD which respectively correspond to the data lines DL1 to DLn.

The display device DD may include a printed circuit board PCB connected to the pads PD. Connection pads PCB-PD may be disposed on the printed circuit board PCB, and the connection pads PCB-PD may be connected to the pads PD.

A timing controller (not illustrated) may be disposed on the printed circuit board PCB. The timing controller may be connected to the pads PD via the printed circuit board. The timing controller may control operations of the scan driver SDV, the data driver DDV, and/or the emission driver EDV. The timing controller may generate a scan control signal, a data control signal, and/or an emission control signal in response to control signals received from the outside.

The scan control signal may be provided to the scan driver SDV via the first control line CSL1. The emission control signal may be provided to the emission driver EDV via the second control line CSL2. The data control signal may be provided to the data driver DDV. The timing controller may receive image signals from the outside, convert data formats of the image signals so as to meet interface specifications of the data driver DDV, and provide the converted signals to the data driver DDV.

The scan driver SDV may generate a plurality of scan signals in response to a scan control signal. The scan signals may be applied to the pixels PX via the scan lines SL1 to SLm. The scan signals may be sequentially applied to the pixels PX.

The data driver DDV may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive the data voltages in response to the scan signals. The pixels PX may display images by emitting light having luminances corresponding to the data voltages in response to the emission signals. An emission time of the pixels PX may be controlled by the emission signals.

A voltage generator (not illustrated) may be disposed on the printed circuit board PCB. The voltage generator may be connected to the pads PD via the printed circuit board. The voltage generator may generate the first voltage and/or the second voltage. The first voltage and/or the second voltage may be applied to the first power supply line PL1 and/or the second power supply line PL2, respectively.

The pixels PX may each, or one or more, include a light-emitting element. The first voltage may be applied to an anode of a light-emitting element, and the second voltage may be applied to a cathode of a light-emitting element. The light-emitting element may receive the first voltage and the second voltage to be operated.

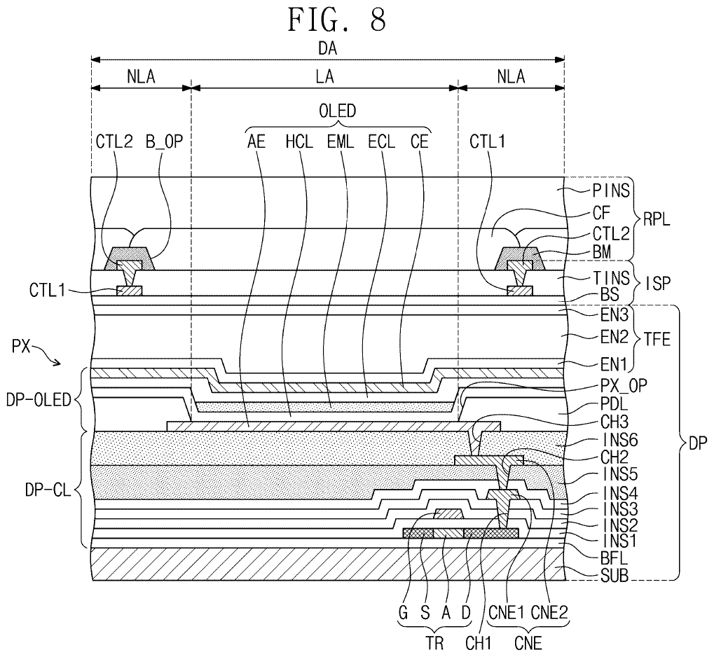

FIG. 8 is an example of a cross-sectional view of one pixel illustrated in FIG. 7.

For example, FIG. 8 illustrates a cross-section of an input-sensing unit ISP and an anti-reflection layer RPL corresponding to one pixel together with a cross-section of a pixel PX.

Referring to FIG. 8, a display panel DP may include the pixel PX, and the pixel PX may include a transistor TR and/or a light-emitting element OLED. The light-emitting element OLED may include a first electrode AE (or an anode), a second electrode CE (or a cathode), a hole control layer HCL, an electron control layer ECL, and/or a light-emitting layer EML.

The transistor TR and/or the light-emitting element OLED may be disposed on a substrate SUB. One transistor TR is illustrated in the drawing for ease of explanation, but substantially, the pixel PX may include a plurality of transistors and at least one capacitor for driving the light-emitting element OLED.

A display region DA may include a light-emitting region LA corresponding to each, or one or more, of the pixels PX and/or a non-light-emitting region NLA around the light-emitting region LA. The light-emitting element OLED may be disposed in the light-emitting region LA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or a metal oxide.

The semiconductor pattern may be doped with an N-type dopant or a P-type dopant. The semiconductor pattern may include a highly-doped region and a lightly-doped region. The highly-doped region may have conductivity higher than that of the lightly-doped region, and substantially serve as a source electrode and a drain electrode of the transistor TR. The lightly-doped region may substantially correspond to an active (or a channel) of the transistor.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and/or a second connection electrode CNE2 for connecting the transistor TR and the light-emitting element OLED. The first connection electrode CNE1 may be disposed on the third insulating layer INS3 and be connected to the drain D via a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 via a second contact hole CH2 defined in the fourth and fifth insulating layers INS4 and INS5.

A sixth insulating layer INS6 may be disposed on the second connection electrode CNE2. The layers ranging from the buffer layer BFL to the sixth insulating layer INS6 may be defined as a circuit element layer DP-CL. The first insulating layer INS1 to the sixth insulating layer INS6 may each, or one or more, be an inorganic layer or an organic layer.

A first electrode AE may be disposed on the sixth insulating layer INS6. The first electrode AE may be connected to the second connection electrode CNE2 via a third contact hole CH3 defined in the sixth insulating layer INS6. A pixel-defining film PDL, in which a pixel opening PX_OP for exposing a predetermined, or alternatively given, portion of the first electrode AE is defined, may be disposed on the first electrode AE and the sixth insulating layer INS6. The first electrode AE, the hole control layer HCL, the light-emitting layer EML, the electron control layer ECL, and/or a second electrode CE may overlap the pixel opening PX_OP. A region overlapping the pixel opening PX_OP may be defined as the light-emitting element OLED.

The hole control layer HCL may be disposed on the first electrode AE and the pixel-defining film PDL. The hole control layer HCL may include a hole transport layer and/or a hole injection layer.

The light-emitting layer EML may be disposed on the hole control layer HCL. The light-emitting layer EML may be disposed in a region corresponding to the pixel opening PX_OP. The light-emitting layer EML may include an organic material and/or an inorganic material. The light-emitting layer EML may generate light having one color of red, green, or blue.

The electron control layer ECL may be disposed on the light-emitting layer EML and/or the hole control layer HCL. The electron control layer ECL may include an electron transport layer and/or an electron injection layer. The hole control layer HCL and/or the electron control layer ECL may be disposed in the light-emitting region LA and the non-light-emitting region NLA in common.

The second electrode CE may be disposed on the electron control layer ECL. The second electrode CE may be disposed in the pixels PX in common. The layer, on which the light-emitting element OLED is disposed, may be defined as a display element layer DP-OLED.

A thin-film encapsulation layer TFE may be disposed on the second electrode CE to cover the pixels PX. The thin-film encapsulation layer TFE may include a first encapsulation layer EN1 disposed on the second electrode CE and/or a second encapsulation layer EN2 disposed on the first encapsulation layer EN1, and/or a third encapsulation layer EN3 disposed on the second encapsulation layer EN2.

The first and/or third encapsulation layers EN1 and/or EN3 may include an inorganic insulating layer and protect the pixels PX against moisture/oxygen. The second encapsulation layer EN2 may include an organic insulating layer and protect the pixels PX against foreign substances such as dust particles.

The first voltage may be applied to the first electrode AE via the transistor TR, and the second voltage having a level lower than that of the first voltage may be applied to the second electrode CE. Holes and electrons injected into the light-emitting layer EML are combined to form excitons, and the excitons transition to a ground state, so that the light-emitting element OLED may emit light.

The layers, ranging from the substrate SUB to the thin-film encapsulation layer TFE, may be defined as the display panel DP. An input-sensing unit ISP may be disposed on the thin-film encapsulation layer TFE. The input-sensing unit ISP may be manufactured directly on an upper surface of the thin-film encapsulation layer TFE.

A base layer BS may be disposed on the thin-film encapsulation layer TFE. The base layer BS may include an inorganic insulating layer. At least one inorganic insulating layer may be provided on the thin-film encapsulation layer TFE as the base layer BS.

The input-sensing unit ISP may include a first conductive pattern CTL1 and/or a second conductive pattern CTL2 disposed on the first conductive pattern CTL1. The first conductive pattern CTL1 may be disposed on the base layer BS. An insulating layer TINS may be disposed on the base layer BS so as to cover the first conductive pattern CTL1. The insulating layer TINS may include an inorganic insulating layer or an organic insulating layer. The second conductive pattern CTL2 may be disposed on the insulating layer TINS.

The first and/or second conductive patterns CTL1 and/or CTL2 may overlap the non-light-emitting region NLA. Although not illustrated, the first and/or second conductive patterns CTL1 and/or CTL2 may be disposed on the non-light-emitting region NLA between the light-emitting regions LA, and have a mesh shape.

The first and/or second conductive patterns CTL1 and/or CTL2 may form sensing electrodes and/or pen sensing electrodes of the above-described input-sensing unit ISP. For example, the first and second conductive patterns CTL1 and CTL2 having a mesh shape may be separated from each other in a predetermined, or alternatively given, region and form the sensing electrodes and/or pen sensing electrodes. A portion of the second conductive pattern CTL2 may be connected to the first conductive pattern CTL1.

The anti-reflection layer RPL may be disposed on the second conductive pattern CTL2. The anti-reflection layer RPL may include a black matrix BM and/or a plurality of color filters CF. The black matrix BM may overlap the non-light-emitting region NLA, and the color filters CF may respectively overlap the light-emitting regions LA.

The black matrix BM may be disposed on the insulating layer TINS so as to cover the second conductive pattern CTL2. An opening B_OP overlapping the light-emitting region LA and the pixel opening PX_OP may be defined in the black matrix BM. The black matrix BM may absorb and/or block light. The width of the opening B_OP may be greater than the width of the pixel opening PX_OP.

The color filters CF may be disposed on the insulating layer TINS and/or the black matrix BM. The color filters CF may be respectively disposed in the openings B_OP. A planarization insulating layer PINS may be disposed on the color filters CF. The planarization insulating layer PINS may provide a flat upper surface. According to some example embodiments, an overcoat layer may be included in place of the planarization insulating layer PINS.

When external light propagating toward the display panel DP is reflected at the display panel DP and is re-provided to an external user, the external light may be viewed by the user as if reflected from a mirror. In order to reduce or prevent this phenomenon, the anti-reflection layer RPL may include, for example, the color filters CF which display the same colors as the pixels PX of the display panel DP. The color filters CF may filter external light with colors same as those of the pixels PX. In this case, the external light may be invisible or have a reduced visibility to a user.

However, some example embodiments of the inventive concepts are not limited thereto, and the anti-reflection layer RPL may include a polarization film for reducing reflectance for external light. The polarization film may be separately manufactured and be attached to the input-sensing unit ISP via an adhesive layer. The polarization film may include a retarder and/or a polarizer.

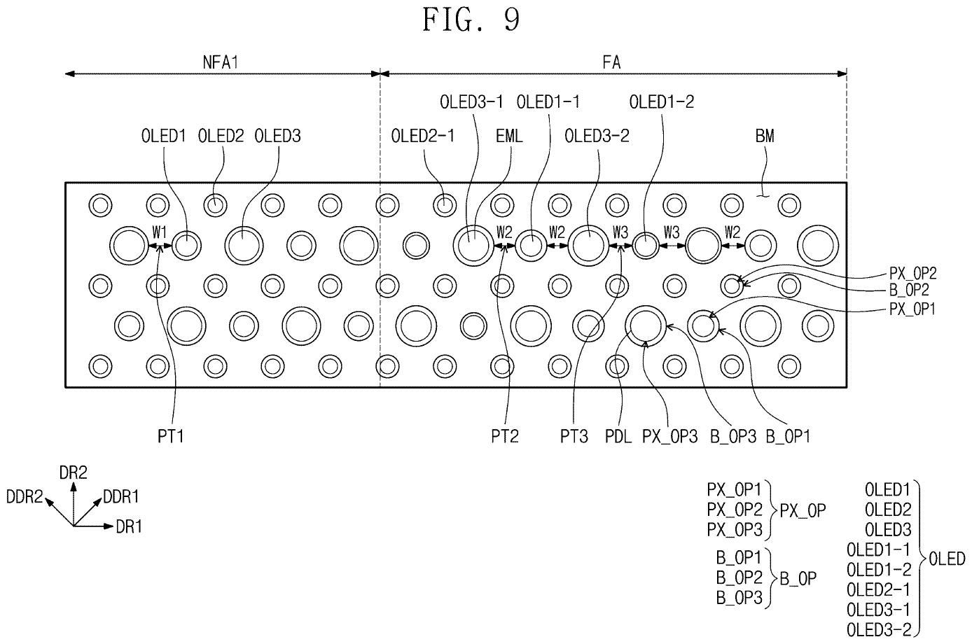

FIG. 9 is a plan view of the display device illustrated in FIG. 5.

FIG. 9 is a view illustrating components of light-emitting elements disposed in a portion of a non-folding part and a portion of a folding part on a plane. For convenience of description, FIG. 9 illustrates an example of a black matrix BM, a light-emitting element OLED, and a pixel-defining film PDL in a first non-folding part NFA1 and a folding part FA. FIG. 9 illustrates an example of the first non-folding part NFA1, but may illustrate the first non-folding part NFA1 or a second non-folding part NFA2 as long as it is possible to indicate a non-folding part.

Referring to FIG. 9, a first oblique direction DDR1 may cross a first direction DR1 and a second direction DR2 on the plane defined by the first direction DR1 and the second direction DR2. A second oblique direction DDR2 may cross the first oblique direction DDR1 on the plane defined by the first direction DR1 and the second direction DR2. The first direction DR1 may be substantially perpendicular to the second direction DR2, and the first oblique direction DDR1 may be substantially perpendicular to the second oblique direction DDR2.

The non-folding parts NFA1 and/or NFA2 may include the light-emitting elements OLED. The light-emitting elements OLED may include a first light-emitting element OLED1, a second light-emitting element OLED2, and/or a third light-emitting element OLED3.

In this specification, a row may correspond to the first direction DR1, and a column may correspond to the second direction DR2. In odd-numbered rows, the second light-emitting elements OLED2 may be arranged in the first direction DR1. In even-numbered rows, the first light-emitting elements OLED1 and the third light-emitting elements OLED3 may be alternately arranged in the first direction DR1. In even-numbered of rows adjacent to each other, the first light-emitting elements OLED1 and the third light-emitting elements OLED3 may be disposed offset from each other. That is, the first light-emitting element OLED1 and the third light-emitting element OLED3 may be alternately arranged in the second direction DR2. Additionally, the second light-emitting elements OLED2 may be disposed between the first light-emitting elements OLED1 and the third light-emitting elements OLED3 in the second direction DR2.

According to the above-described structure, the first light-emitting elements OLED1 and the second light-emitting elements OLED2 may be alternately disposed in the first oblique direction DDR1 and the second oblique direction DDR2. Also, the second light-emitting elements OLED2 and the third light-emitting elements OLED3 may be alternately disposed in the first oblique direction DDR1 and the second oblique direction DDR2. For example, in a state in which the third light-emitting elements OLED3 are disposed between the first light-emitting elements OLED1 in the first direction DR1, the second light-emitting elements OLED2 and the third light-emitting elements OLED3 may be alternately disposed in the first oblique direction DDR1 and the second oblique direction DDR2.

FIG. 9 illustrates the light-emitting elements OLED which are respectively disposed in pixel openings PX_OP1, PX_OP2, and PX_OP3. A plurality of openings B_OP1, B_OP2, and B_OP3 defined by the black matrix BM may have a some size, but the pixel openings PX_OP1, PX_OP2, and PX_OP3 may have different sizes. A first pixel opening PX_OP1 may be greater than a second pixel opening PX_OP2. Accordingly, on a plane, the first light-emitting element OLED1 may be greater than the second light-emitting element OLED2. A third pixel opening PX_OP3 may be greater than the first pixel opening PX_OP1. Accordingly, on a plane, the third light-emitting element OLED3 may be greater than the first light-emitting element OLED1.

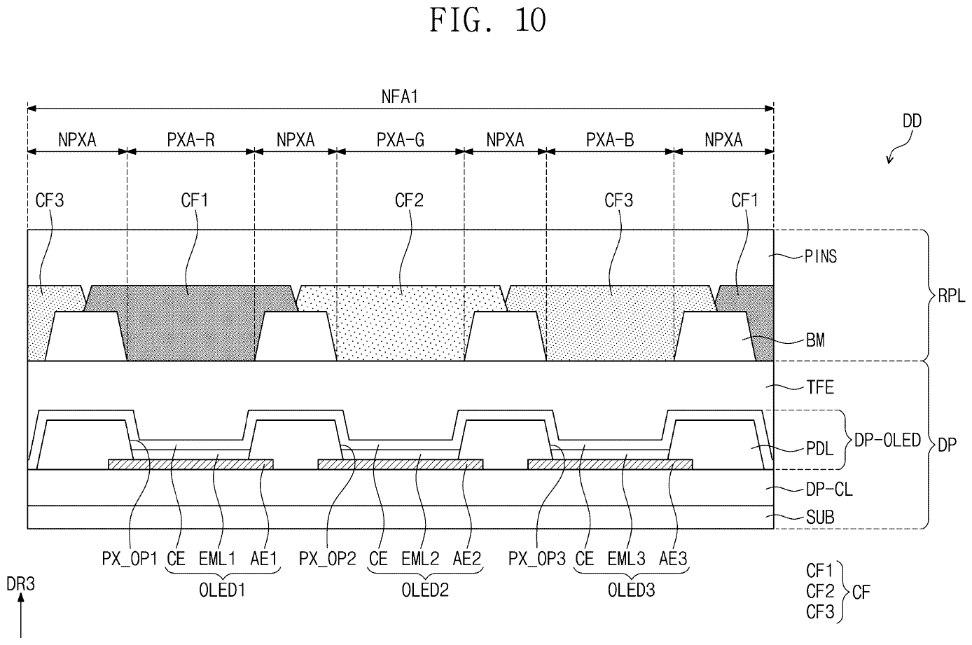

FIG. 10 is an example of a cross-sectional view some pixels adjacent to each other and an anti-reflection layer corresponding to the pixels in a non-folding part.

For convenience of description, in FIG. 10, a circuit element layer DP-CL and a thin-film encapsulation layer TFE are illustrated as a single layer, and the window WIN (see FIG. 5) is omitted. FIG. 10 further distinguishably illustrates a black matrix BM and color filters CF1, CF2, and CF3.

Referring to FIGS. 9 and 10, a display device DD may include a display panel DP and/or an anti-reflection layer RPL.

The display panel DP may include a folding part FA and/or non-folding parts NFA1 and/or NFA2 adjacent to the folding part FA. FIG. 10 illustrates a first non-folding part NFA1 as an example, but example embodiments of the inventive concepts are not limited thereto. The folding part FA and the non-folding parts NFA1 and/or NFA2 may be adjacent to each other in the first direction DR1. The non-folding parts NFA1 and/or NFA2 may include a first light-emitting element OLED1, a second light-emitting element OLED2, and/or a third light-emitting element OLED3.

The first light-emitting element OLED1 may include a first anode AE1, a first light-emitting layer EML1, and/or a portion of a cathode CE. The second light-emitting element OLED2 may include a second anode AE2, a second light-emitting layer EML2, and/or a portion of the cathode CE. The third light-emitting element OLED3 may include a third anode AE3, a third light-emitting layer EML3, and/or a portion of the cathode CE.

The first to third anodes AE1, AE2, and/or AE3 may be provided in the form of a plurality of patterns. First to third pixel openings PX_OP1, PX_OP2, and/or PX_OP3 may be defined in a pixel-defining film PDL. The first pixel opening PX_OP1 may expose at least a portion of the first anode AE1. The second pixel opening PX_OP2 may expose at least a portion of the second anode AE2. The third pixel opening PX_OP3 may expose at least a portion of the third anode AE3.

The first to third light-emitting layers EML1, EML2, and/or EML3 may be disposed on the first to third anodes AE1, AE2, and/or AE3 and/or the pixel-defining film PDL. The plurality of pixel openings PX_OP1, PX_OP2, and/or PX_OP3 for disposing the first light-emitting element OLED1, the second light-emitting element OLED2, and/or the third light-emitting element OLED3 may be defined in the pixel-defining film PDL. For example, the first to third light-emitting layers EML1, EML2, and/or EML3 may be disposed in the first to third pixel openings PX_OP1, PX_OP2, and/or PX_OP3, respectively. The first light-emitting layer EML1 may be disposed in the first pixel opening PX_OP1, the second light-emitting layer EML2 may be disposed in the second pixel opening PX_OP2, and/or the third light-emitting layer EML3 may be disposed in the third pixel opening PX_OP3. The cathode CE may be disposed on the first to third light-emitting layers EML1, EML2, and/or EML3, and/or the pixel-defining film PDL.

FIG. 10 illustrates an example showing that the first to third light-emitting layers EML1, EML2, and EML3 are disposed on the first to third anodes AE1, AE2, and AE3 and the pixel-defining film PDL, but some example embodiments of the inventive concepts are not limited thereto. For example, the first to third light-emitting layers EML1, EML2, and/or EML3 may be disposed only on the first to third anodes AE1, AE2, and/or AE3.

The first to third light-emitting layers EML1, EML2, and/or EML3 may provide different colors. For example, the first light-emitting layer EML1 may provide a red color, the second light-emitting layer EML2 may provide a green color, and/or the third light-emitting layer EML3 may provide a blue color.

The first light-emitting element OLED1, a (1-1)-th light-emitting element OLED1-1, and/or a (1-2)-th light-emitting element OLED1-2 may generate red colors. The second light-emitting element OLED2 and/or a (2-1)-th light-emitting element OLED2-1 may generate green colors. The third light-emitting element OLED3, a (3-1)-th light-emitting element OLED3-1, and/or a (3-2)-th light-emitting element OLED3-2 may generate blue colors.

The anti-reflection layer RPL may include a black matrix BM, a plurality of color filters CF, and/or a planarization insulating layer PINS.

The plurality of the color filters CF may overlap the first to third light-emitting elements OLED1, OLED2, and/or OLED3. The color filters CF may include first to third color filters CF1, CF2, and/or CF3.

The black matrix BM is a layer having a black color, and in some example embodiments, the black matrix BM may include a black coloring agent. The black coloring agent may include a black dye and/or a black pigment. The black coloring agent may include carbon black, metal such as chromium, and/or oxides thereof. However, this is presented as an example, and a material constituting the black matrix BM is not particularly limited as long as the material absorbs light.

The black matrix BM may reduce or prevent the external light from being reflected by the first conductive pattern CTL1 (see FIG. 8) and/or the second conductive pattern CTL2 (see FIG. 8). The black matrix BM may be disposed to overlap the pixel-defining film PDL.

First to third openings B_OP1, B_OP2, and/or B_OP3 may be defined in the black matrix BM. The first to third openings B_OP1, B_OP2, and/or B_OP3 of the black matrix BM may overlap the first to third pixel openings PX_OP1, PX_OP2, and/or PX_OP3 of the pixel-defining film PDL. The first opening B_OP1 may overlap the first pixel opening PX_OP1, the second opening B_OP2 may overlap the second pixel opening PX_OP2, and/or the third opening B_OP3 may overlap the third pixel opening PX_OP3. In the first light-emitting element OLED1, the second light-emitting element OLED2, and/or the third light-emitting element OLED3, the areas of the first to third openings B_OP1, B_OP2, and/or B_OP3 may be greater than the areas of the first to third pixel openings PX_OP1, PX_OP2, and/or PX_OP3.

The first to third openings B_OP1, B_OP2, and/or B_OP3 of the black matrix BM may define first to third pixel regions PXA-R, PXA-G, and/or PXA-B. The first to third pixel regions PXA-R, PXA-G, and/or PXA-B may be respectively defined as regions in which light generated from the first to third light-emitting elements OLED1, OLED2, and/or OLED3 are emitted to the outside.

The black matrix BM may be disposed between a first color filter CF1 and a second color filter CF2, between the first color filter CF1 and a third color filter CF3, and/or between the second color filter CF2 and the third color filter CF3.

The color filter CF may include the first color filter CF1, the second color filter CF2, and/or the third color filter CF3. The first color filter CF1, the second color filter CF2, and/or the third color filter CF3 may transmit light generated from the first to third light-emitting elements OLED1, OLED2, and/or OLED3, and block some light having specific wavelengths among the external light while corresponding to the first to third light-emitting elements OLED1, OLED2, and/or OLED3.

The first color filter CF1 may transmit a first color, the second color filter CF2 may transmit a second color, and/or the third color filter CF3 may transmit a third color. The first color, the second color, and/or the third color may be different from each other. For example, the first color may be red, the second color may be green, and/or the third color may be blue. The first color filter CF1, the second color filter CF2, and/or the third color filter CF3 may reduce the external light from being reflected by the first to third anodes AE1, AE2, and/or AE3 or the cathode CE.

The first color filter CF1, the second color filter CF2, and/or the third color filter CF3 may overlap at least the first to third pixel regions PXA-R, PXA-G, and/or PXA-B. Specifically, the first color filter CF1 may overlap with the first light-emitting element OLED1, the second color filter CF2 may overlap with the second light-emitting element OLED2, and/or the third color filter CF3 may overlap with the third light-emitting element OLED3. A portion of each, or one or more, of the first color filter CF1, the second color filter CF2, and/or the third color filter CF3 may also overlap a non-pixel region NPXA. That is, a portion of each, or one or more, of the first color filter CF1, the second color filter CF2, and/or the third color filter CF3 may be disposed on the black matrix BM.

The planarization insulating layer PINS may cover the black matrix BM, the first color filter CF1, the second color filter CF2, and/or the third color filter CF3. The planarization insulating layer PINS may include an organic material and provide a flat upper surface.

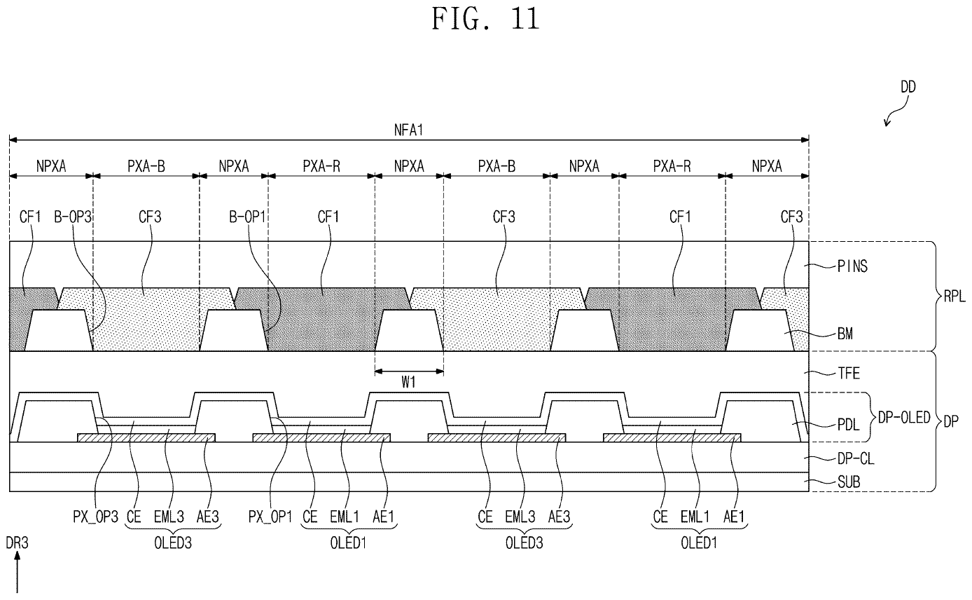

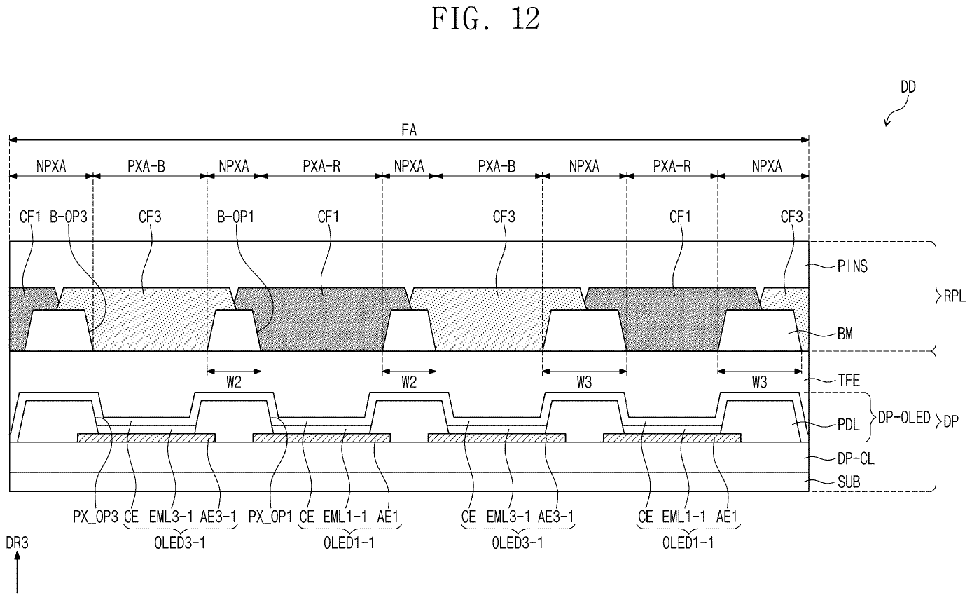

FIG. 11 is an example of a cross-sectional view illustrating some pixels adjacent to each other and an anti-reflection layer corresponding to the pixels in a non-folding part. FIG. 12 is an example of a cross-sectional view illustrating some pixels adjacent to each other and an anti-reflection layer corresponding to the pixels in a folding part.

For convenience of description, in FIGS. 11 and 12, a circuit element layer DP-CL and a thin-film encapsulation layer TFE are illustrated as a single layer, and the window WIN (see FIG. 5) is omitted. FIGS. 11 and 12 further illustrate a black matrix BM and color filters CF1, CF2, and CF3.

Referring to FIGS. 9, 11, and 12, the display panel DP may include the folding part FA. The folding part FA may include the (1-1)-th light-emitting element OLED1-1, the (1-2)-th light-emitting element OLED1-2, the (2-1)-th light-emitting element OLED2-1, the (3-1)-th light-emitting element OLED3-1, and/or the (3-2)-th light-emitting element OLED3-2. The (1-1)-th light-emitting element OLED1-1 and the (3-1)-th light-emitting element OLED3-1 may be adjacent to each other in the first direction DR1. The (1-2)-th light-emitting element OLED1-2 and the (3-2)-th light-emitting element OLED3-2 may be arranged in the first direction DR1 and be adjacent to each other in the first direction DR1.

The display panel DP may include a pixel-defining film PDL. The pixel-defining film PDL may include a plurality of pixel openings PX_OP1, PX_OP2, and/or PX_OP3. The (1-1)-th light-emitting element OLED1-1, the (1-2)-th light-emitting element OLED1-2, the (2-1)-th light-emitting element OLED2-1, the (3-1)-th light-emitting element OLED3-1, and/or the (3-2)-th light-emitting element OLED3-2 may be disposed in the pixel openings PX_OP1, PX_OP2, and PX_OP3.

An anti-reflection layer RPL may include the color filters CF, the black matrix BM, and a planarization insulating layer PINS.

The color filters CF may be disposed on the display panel DP. When viewed on a plane, the color filters CF may overlap the (1-1)-th light-emitting element OLED1-1, the (2-1)-th light-emitting element OLED2-1, and/or the (3-1)-th light-emitting element OLED3-1. The black matrix BM may be disposed between the color filters CF.

The openings B_OP1, B_OP2, and/or B_OP3 may be defined in the black matrix BM. The areas of the openings B_OP1, B_OP2, and/or B_OP3 may be greater than the areas of the pixel openings PX_OP1, PX_OP2, and/or PX_OP3 in each, or one or more, of the (1-1)-th light-emitting element OLED1-1, the (1-2)-th light-emitting element OLED1-2, the (2-1)-th light-emitting element OLED2-1, the (3-1)-th light-emitting element OLED3-1, and/or the (3-2)-th light-emitting element OLED3-2.

When viewed on a plane, the first light-emitting element OLED1 and the third light-emitting element OLED3 may be disposed in the non-folding parts NFA1 and NFA2. A first portion PT1 of the black matrix BM disposed between the first light-emitting element OLED1 and the third light-emitting element OLED3 may have a first width W1.

When viewed on a plane, the (1-1)-th light-emitting element OLED1-1 and/or the (3-1)-th light-emitting element OLED3-1 may be disposed in the folding part FA. A second portion PT2 of the black matrix BM disposed between the (1-1)-th light-emitting element OLED1-1 and the (3-1)-th light-emitting element OLED3-1 may have a second width W2.

When viewed on a plane, the (1-2)-th light-emitting element OLED1-2 and/or the (3-2)-th light-emitting element OLED3-2 may be disposed in the folding part FA. A third portion PT3 of the black matrix BM disposed between the (1-2)-th light-emitting element OLED1-2 and the (3-2)-th light-emitting element OLED3-2 may have a third width W3.

The first width W1, the second width W2, and/or the third width W3 may be adjacent to each other in the first direction DR1. The first width W1, the second width W2, and/or the third width W3 may be defined as widths with respect to the first direction DR1. That is, the first width W1, the second width W2, and/or the third width W3 may be respectively defined as distances between the openings B_OP1, B_OP2, and/or B_OP3 which define the first width W1, the second width W2, and/or the third width W3.

The first width W1 may differ from the second width W2. The third width W3 may differ from the first width W1 and/or the second width W2. The first width W1 may be greater than the second width W2. The third width W3 may be greater than the first width W1. The second portion PT2 having the second width W2, and the third portion PT3 having the third width W3 may be alternately arranged in the first direction DR1. In this case, the black matrix BM may have the same thickness.

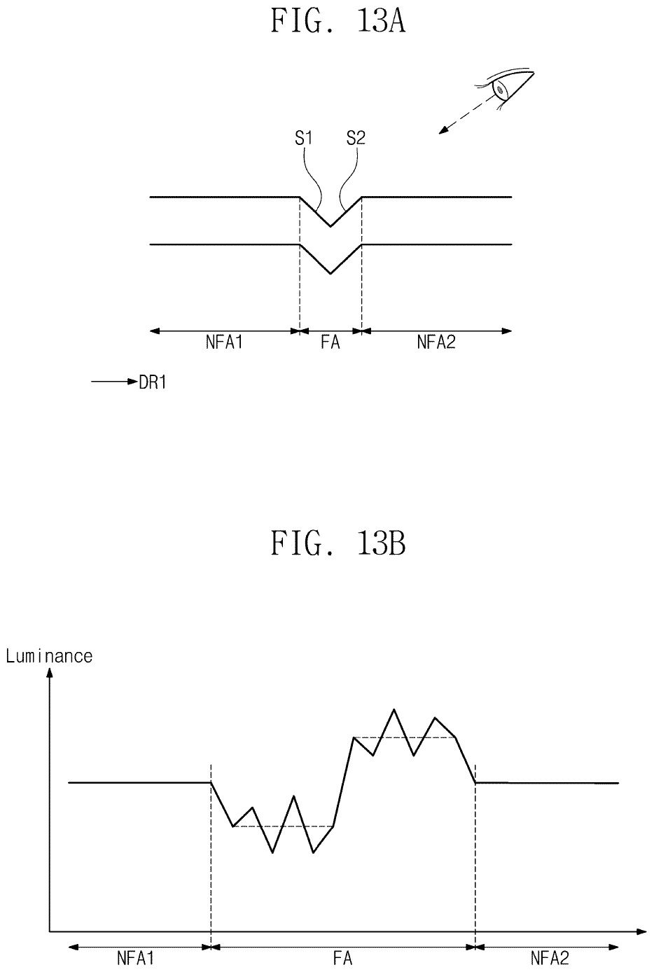

FIG. 13A is an enlarged view of a folding part and a non-folding part. FIG. 13B is a graph showing luminances of the folding part and the non-folding part.

Referring to FIGS. 9, 12, 13A, and 13B, the folding part FA may be deformed by being repeatedly folded and unfolded. Images in a deformed region are not clearly visible, which may result in visibility degradation. For example, images may appear to be wrinkles and/or images may be separately recognized.

For example, according to a user's viewing angle with respect to the first direction DR1, luminances may be visually recognized as non-uniform. When a user's eye gaze is focused on a point as illustrated in FIG. 13A, a first side S1 may be visually recognized as darker, and a second side S2 may be visually recognized as brighter. In this case, visibility of images may be deteriorated.

Areas of the black matrix BM (see FIG. 12) may affect luminances of the light-emitting elements OLED. According to some example embodiments of the inventive concepts, widths of the black matrix BM in the first direction DR1 may not be constant and may be repeatedly varied. As the areas of the black matrix BM are varied, the luminances of the light-emitting elements OLED in the first direction DR1 may be varied.

For example, a luminance of the (1-1)-th light-emitting element OLED1-1 arranged in the first direction DR1 may be repeatedly varied to a first luminance and a second luminance which are different from each other. Additionally, a luminance of the (3-1)-th light-emitting element OLED3-1 may be repeatedly varied to a third luminance and a fourth luminance different from each other. Therefore, the luminances of the (1-1)-th light-emitting element OLED1-1 and the (3-1)-th light-emitting element OLED3-1 may be repeatedly varied in the first direction DR1.

When intensities of the luminances are repeatedly varied, images may be more clearly viewed due to a dithering effect. For example, wrinkle-shaped portions in a deformed folding part FA may be decreased, and/or an image break-up phenomenon may be reduced.

According to some example embodiments of the inventive concepts, the second width W2 and the third width W3 are described as the widths of the black matrix BM of the color filters CF1 and CF3 corresponding to the first light-emitting element OLED1 and the third light-emitting element OLED3. However, as long as visibility of the display panel DP may be improved due to a luminance difference at a boundary of a wrinkled portion of the folding part FA by controlling the widths of the black matrix BM, the second width W2 and/or the third width W3 may be a width of the black matrix BM of the color filters CF corresponding to one of the first light-emitting element OLED1, the second light-emitting element OLED2 and/or the third light-emitting element OLED3.

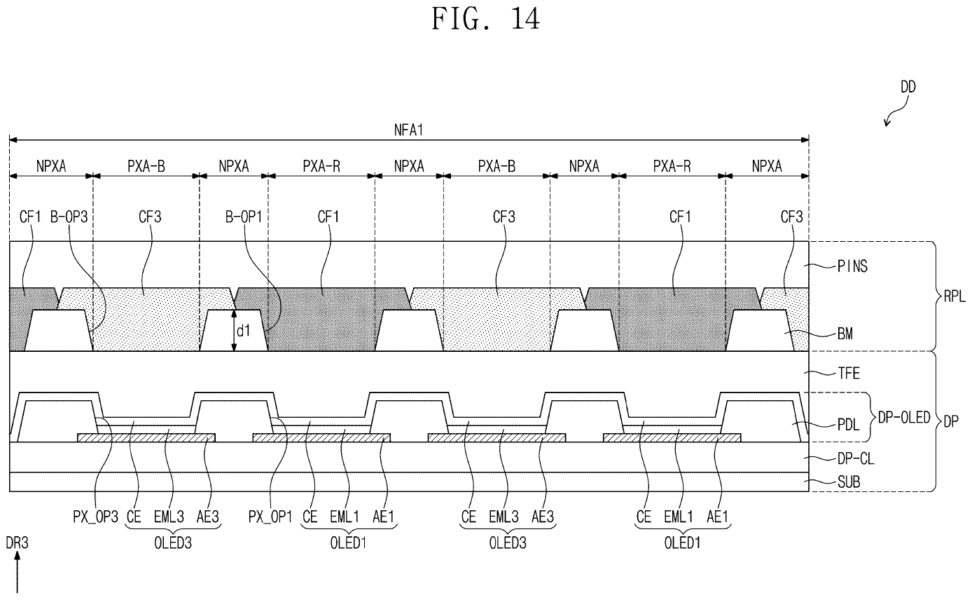

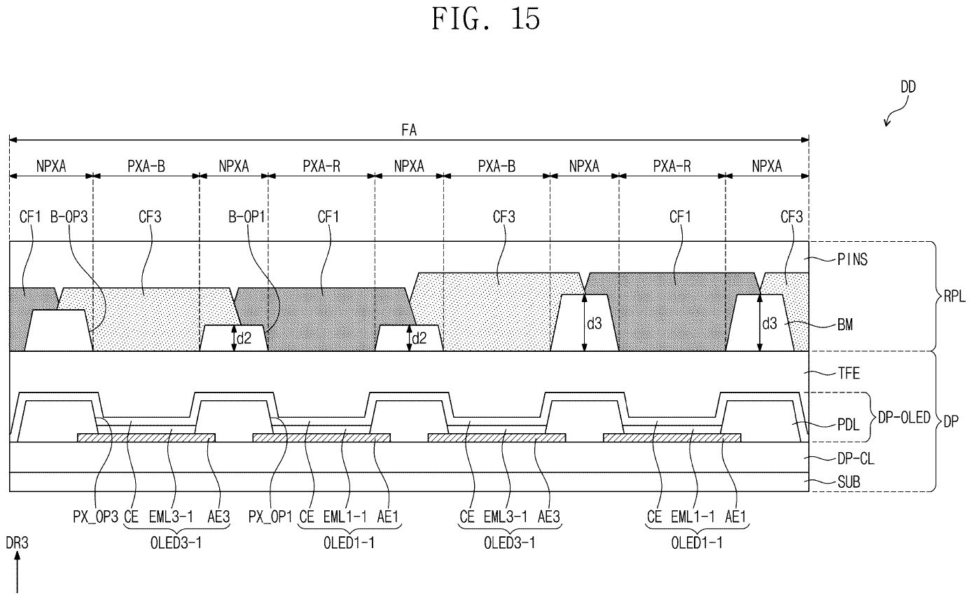

FIG. 14 is an example of a cross-sectional view illustrating some pixels adjacent to each other and an anti-reflection layer corresponding to the pixels in a non-folding part. FIG. 15 is an example of a cross-sectional view illustrating some pixels adjacent to each other and an anti-reflection layer corresponding to the pixels in a folding part.

For convenience of description, in FIGS. 14 and 15, a circuit element layer DP-CL and a thin-film encapsulation layer TFE are illustrated as a single layer, and the window WIN (see FIG. 5) is omitted. FIGS. 14 and 15 further distinguishably illustrate a black matrix BM and color filters CF1, CF2, and CF3.

Referring to FIGS. 9, 14, and 15, when viewed on a plane, the first light-emitting element OLED1 and/or the third light-emitting element OLED3 may be disposed in the non-folding parts NFA1 and NFA2. The first portion PT1 of the black matrix BM disposed between the first light-emitting element OLED1 and the third light-emitting element OLED3 may have a first thickness D1.

When viewed on a plane, the (1-1)-th light-emitting element OLED1-1 and/or the (3-1)-th light-emitting element OLED3-1 may be disposed in the folding part FA. The second portion PT2 of the black matrix BM disposed between the (1-1)-th light-emitting element OLED1-1 and the (3-1)-th light-emitting element OLED3-1 may have a second thickness D2.

When viewed on a plane, the (1-2)-th light-emitting element OLED1-2 and/or the (3-2)-th light-emitting element OLED3-2 may be disposed in the folding part FA. The third portion PT3 of the black matrix BM disposed between the (1-2)-th light-emitting element OLED1-2 and the (3-2)-th light-emitting element OLED3-2 may have a third thickness D3.

The first thickness D1, the second thickness D2, and/or the third thickness D3 may be defined as thicknesses with respect to the third direction DR3. The first thickness D1, the second thickness D2, and the third thickness D3 may differ from each other. For example, the first thickness D1 may be greater than the second thickness D2. The third thickness D3 may be greater than the first thickness D1. In this case, the black matrix BM may have the same width in the first direction DR1.

Referring to FIGS. 9, 13A, 13B, 14, and 15, in some example embodiments of the inventive concepts, the thicknesses of the black matrix BM in the first direction DR1 may not be constant and be repeatedly varied. As the thicknesses of the black matrix BM are varied, the luminances of the light-emitting elements OLED in the first direction DR1 may be varied.

For example, the luminance of the (1-1)-th light-emitting element OLED1-1 arranged in the first direction DR1 may be repeatedly varied to the first luminance and the second luminance which are different from each other. Additionally, the luminance of the (3-1)-th light-emitting element OLED3-1 may be repeatedly varied to the third luminance and the fourth luminance different from each other. Therefore, the luminances of the (1-1)-th light-emitting element OLED1-1 and the (3-1)-th light-emitting element OLED3-1 may be repeatedly varied in the first direction DR1.

When intensities of the luminances are repeatedly varied, images may be more clearly viewed due to a dithering effect. For example, wrinkle-shaped portions in the deformed folding part FA may be decreased, and/or an image break-up phenomenon may be reduced.

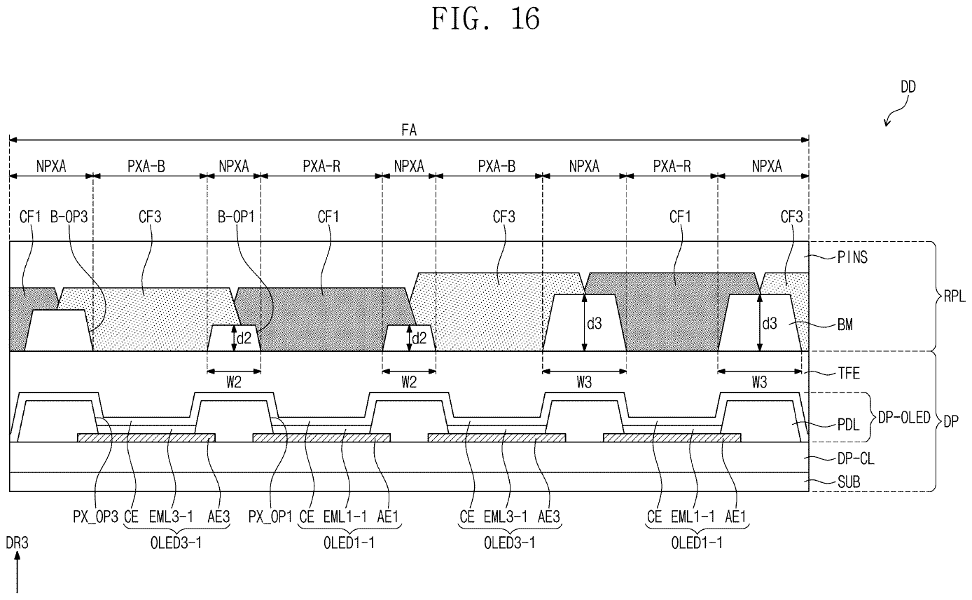

FIG. 16 is an example of a cross-sectional view illustrating some pixels adjacent to each other and an anti-reflection layer corresponding to the pixels in a folding part.

For convenience of description, in FIG. 16, a circuit element layer DP-CL and a thin-film encapsulation layer TFE are illustrated as a single layer, and the window WIN (see FIG. 5) is omitted. FIG. 16 further distinguishably illustrates a black matrix BM and color filters CF1, CF2, and CF3.

Referring to FIGS. 9 and 16, when viewed on a plane, the first light-emitting element OLED1 and/or the third light-emitting element OLED3 may be disposed in the non-folding parts NFA1 and/or NFA2. The first portion PT1 of the black matrix BM disposed between the first light-emitting element OLED1 and the third light-emitting element OLED3 may have a first width W1 and/or a first thickness D1.

When viewed on a plane, the (1-1)-th light-emitting element OLED1-1 and/or the (3-1)-th light-emitting element OLED3-1 may be disposed in the folding part FA. The second portion PT2 of the black matrix BM disposed between the (1-1)-th light-emitting element OLED1-1 and the (3-1)-th light-emitting element OLED3-1 may have a second width W2 and/or a second thickness D2.

When viewed on a plane, the (1-2)-th light-emitting element OLED1-2 and/or the (3-2)-th light-emitting element OLED3-2 may be disposed in the folding part FA. The third portion PT3 of the black matrix BM disposed between the (1-2)-th light-emitting element OLED1-2 and the (3-2)-th light-emitting element OLED3-2 may have a third width W3 and a third thickness D3.

The first width W1, the second width W2, and/or the third width W3 may differ from each other. Also, the first thickness D1, the second thickness D2, and/or the third thickness D3 may differ from each other.

Referring to FIGS. 9, 13A, 13B, and 16, in some example embodiments of the inventive concepts, the widths and/or thicknesses of the black matrix BM in the first direction DR1 may not be constant and may be repeatedly varied. As the width and/or the thickness of the black matrix BM are varied, the luminances of the light-emitting elements OLED in the first direction DR1 may be varied.

For example, the luminance of the (1-1)-th light-emitting element OLED1-1 arranged in the first direction DR1 may be repeatedly varied to the first luminance and the second luminance which are different from each other. Additionally, the luminance of the (3-1)-th light-emitting element OLED3-1 may be repeatedly varied to the third luminance and the fourth luminance different from each other. Therefore, the luminances of the (1-1)-th light-emitting element OLED1-1 and the (3-1)-th light-emitting element OLED3-1 may be repeatedly varied in the first direction DR1.

When intensities of the luminances are repeatedly varied, images may be more clearly viewed due to a dithering effect. For example, wrinkle-shaped portions in the deformed folding part FA may be decreased, or an image break-up phenomenon may be reduced.

As described above, areas of a black matrix may affect luminances of light-emitting elements. According to some example embodiments of the inventive concepts, widths of the black matrix in a first direction may not be constant and may be repeatedly varied. As areas of the black matrix are varied, the luminances of the light-emitting elements in the first direction may be varied.

When intensities of the luminances are repeatedly varied, images may be more clearly viewed due to a dithering effect. For example, wrinkle-shaped portions in a deformed folding part may be decreased, and/or an image break-up phenomenon may be reduced.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In the above, description has been made with reference to some example embodiments of the inventive concepts, but those skilled or of ordinary skill in the art may understand that various modifications and/or changes may be made to the inventive concepts insofar as such modifications and changes do not depart from the spirit and technical scope of the inventive concepts set forth in the claims to be described later.

Therefore, the technical scope of the inventive concepts are not to be limited to the contents stated in the detailed description of the specification, but should be determined by the claims.

What is claimed is:

1. A display device comprising:
a display panel including
a plurality of light-emitting elements,
a folding part including a (1-1)-th light-emitting element, a (2-1)-th light-emitting element, and a (3-1)-th light-emitting element, and
a non-folding part adjacent to the folding part, the non-folding part including a first light-emitting element, a second light-emitting element, and a third light-emitting element;
a plurality of color filters on the display panel, the plurality of color filters overlapping the plurality of light-emitting elements when viewed on a plane; and
a black matrix between the plurality of color filters,
wherein, when viewed on the plane, a first portion of the black matrix between the first light-emitting element and the third light-emitting element has a first width, and
wherein a second portion of the black matrix between the (1-1)-th light-emitting element and the (3-1)-th light-emitting element has a second width different from the first width.

2. The display device of claim 1, wherein
the folding part and the non-folding part are adjacent to each other in a first direction, the first light-emitting element and the third light-emitting element are adjacent to each other in the first direction, and the (1-1)-th light-emitting element and the (3-1)-th light-emitting element are adjacent to each other in the first direction, and
the first width and the second width are widths with respect to the first direction.

3. The display device of claim 2, further comprising a (1-2)-th light-emitting element and a (3-2)-th light-emitting element adjacent to each other in the first direction and in a row with the (1-1)-th and (3-1)-th light-emitting elements in the first direction,
wherein when viewed on the plane, a third portion of the black matrix between the (1-2)-th light-emitting element and the (3-2)-th light-emitting element in the first direction has a third width different from the first width and the second width in the first direction.

4. The display device of claim 3, wherein the (1-2)-th light-emitting element and the (3-2)-th light-emitting element are in the folding part.

5. The display device of claim 3, wherein the first width is greater than the second width.

6. The display device of claim 3, wherein the third width is greater than the first width.

7. The display device of claim 3, wherein the first portion of the black matrix, the second portion of the black matrix, and the third portion of the black matrix have a same thickness.

8. The display device of claim 3, wherein a first thickness of the first portion, a second thickness of the second portion, and a third thickness of the third portion are different from each other in a direction perpendicular to the plane.

9. The display device of claim 8, wherein the first thickness is greater than the second thickness.

10. The display device of claim 8, wherein the third thickness is greater than the first thickness.

11. The display device of claim 3, further comprising a pixel-defining film defining a plurality of pixel openings exposing the plurality of light-emitting elements,
wherein the black matrix defines a plurality of openings overlapping the pixel openings and
wherein an area of a respective opening is greater than an area of the pixel opening the respective opening overlaps.

12. The display device of claim 11, wherein the first width, the second width, and the third width are adjacent to each other in the first direction, and are distances between the openings which respectively define the first, second, and third widths.

13. The display device of claim 3, wherein
the first light-emitting element, the (1-1)-th light-emitting element, and the (1-2)-th light-emitting element are configured to generate a red color,
the second light-emitting element and the (2-1)-th light-emitting element are configured to generate a green color, and
the third light-emitting element, the (3-1)-th light-emitting element, and the (3-2)-th light-emitting element are configured to generate a blue color.

14. The display device of claim 3, wherein the second portion having the second width and the third portion having the third width are alternately arranged in the first direction.

15. A display device comprising:
a plurality of light-emitting elements;
a display panel including
a folding part including a (1-1)-th light-emitting element, a (1-2)-th light-emitting element, a (2-1)-th light-emitting element, a (3-1)-th light-emitting element, and a (3-2)-th light-emitting element, and
a non-folding part adjacent to the folding part, the non-folding part including a first light-emitting element, a second light-emitting element, and a third light-emitting element;
a plurality of color filters on the display panel and overlapping the plurality of light emitting elements when viewed on a plane; and
a black matrix between the plurality of color filters,
wherein when viewed on the plane, a first portion of the black matrix between the first light-emitting element and the third light-emitting element has a first width, a second portion of the black matrix between the (1-1)-th light-emitting element and the (3-1)-th light-emitting element has a second width, and a third portion of the black matrix between the (1-2)-th light-emitting element and the (3-2)-th light-emitting element has a third width, and
wherein the third width is greater than the first width, and the first width is greater than the second width.

16. The display device of claim 15, wherein the second portion having the second width and the third portion having the third width are alternately arranged in the first direction.

17. The display device of claim 15, wherein a first thickness of the first portion, a second thickness of the second portion, and a third thickness of the third portion are different from each other in a direction perpendicular to the plane.

18. The display device of claim 17, wherein
the first width, the second width, and the third width of the black matrix are equal to each other,
the third thickness is greater than the first thickness, and
the first thickness is greater than the second thickness.

19. An electronic device comprising:
a camera;
a display device configured to display an image corresponding to a captured image obtained via the camera; and
a case accommodating the display device and the camera,
wherein the display device includes
a plurality of light-emitting elements,
a display panel including
a folding part including a (1-1)-th light-emitting element, a (2-1)-th light-emitting element, and a (3-1)-th light-emitting element, and
a non-folding part adjacent to the folding part, the non-folding part including a first light-emitting element, a second light-emitting element, and a third light-emitting element,
a plurality of color filters on the display panel and overlapping the plurality of light emitting elements when viewed on a plane, and
a black matrix between the plurality of color filters, and
wherein, when viewed on the plane, a first portion of the black matrix between the first light-emitting element and the third light-emitting element has a first width, and a second portion of the black matrix between the (1-1)-th light-emitting element and the (3-1)-th light-emitting element has a second width different from the first width.
